(19) United States
(12) Patent Application Publication
(10) Pub. No.: US 2005/0212035 A1
(43) Pub. Date: Sep. 29, 2005

(54) Semiconductor storage device and manufacturing method thereof

(75) Inventors: Yukihiro Utsuno, Aizuwakamatsu (JP); Manabu Nakamura, Aizuwakamatsu (JP); Kentaro Sera, Aizuwakamatsu (JP); Masahiko Higashi, Aizuwakamatsu (JP); Hiroyuki Nansei, Aizuwakamatsu (JP); Hideo Takagi, Aizuwakamatsu (JP); Tatsuya Kajita, Aizuwakamatsu (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU AMD SEMICONDUCTOR LIMITED, Fukushima (JP)

(21) Appl. No.: 11/065,306

(22) Filed: Feb. 25, 2005

Related U.S. Application Data
(63) Continuation of application No. PCT/JP03/08285, filed on Jun. 30, 2003.

(30) Foreign Application Priority Data
Aug. 30, 2002 (JP) 2002-255527

(51) Int. Cl. H01L 29/788

(52) U.S. Cl. 257/315

(57) ABSTRACT

Tunnel insulating films (3) are formed in element regions demarcated by element isolation insulating films (2). Thereafter, for each memory cell, a floating gate (4) is formed, and an ONO film (5) and a control gate (6) are further formed. Next, a plasma insulating film (7) is formed on surfaces of stacked gates. The plasma insulating film is immune to plane orientation of a base film. Therefore, the entire plasma insulating film (7) has a substantially uniform thickness, and consequently, even if the maximum thickness thereof is not as large as that of a thermal oxide film, hydrogen entrance is prevented when the interlayer insulating film is thereafter formed, and electron leakage is also prevented. The reduction in thickness of this insulating film makes it possible to reduce birds' beaks, and efficiency in erase/write of data can be enhanced.

### TECHNICAL FIELD

The present invention relates to a semiconductor storage device suitable as a flash memory and a manufacturing method thereof.

### BACKGROUND ART

A flash memory is a nonvolatile semiconductor storage device that stores data by holding electric charges on a storage film such as a nitride film under a floating gate or a gate electrode. When the electric charges are accumulated on the floating gate, the electric charges are exchanged between a channel and the floating gate via a gate insulating film. When the electric charges are accumulated on the nitride film in an ONO film as the storage film, the electric charges are accumulated on an insulating film itself. Therefore, these insulating films are required to have stable electric characteristics. Unstable characteristics of these insulating films may possibly produce a state in which some memory cell stores data of “1” while another memory cell stores data of “0”, even when the same control voltage is applied, resulting in extremely inferior reliability.

Not only these insulating films but also an insulating film and so on formed around the floating gate or the gate electrode are required to have stable characteristics. This insulating film is formed for the following purpose. After the floating gate or the gate electrode is formed, a sidewall insulating film for later formation of a LDD structure is formed on side faces thereof, and an interlayer insulating film covering the floating gate or the gate electrode is further formed. At this time, if the floating gate or the gate electrode is in direct contact with the sidewall insulating film or the interlayer insulating film, electrons sometimes leak from the floating gate or the gate electrode to the sidewall insulating film and so on. As a result, the electric characteristics of the floating gate or the gate electrode fluctuate. Further, in the steps of forming the sidewall insulating film and the interlayer insulating film, hydrogen-containing gas is sometimes used. At this time, if the hydrogen reaches the gate insulating film or the storage film, hydrogen deterioration or the like occurs, so that the characteristics of the gate insulating film or the storage film fluctuate.

In order to prevent such fluctuation, the insulating film is formed around the gate electrode. In order to achieve such an object, this insulating film is formed to have a thickness of 12 nm or larger at the thickest portion thereof by thermal oxidation at about 900° C. The reason why this insulating film is formed to have a thickness of 12 nm or larger at its thickest portion is that in forming an oxide film by thermal oxidation, the deposition rate of the oxide film differs depending on the plane orientation of its base, for example, a silicon film constituting the gate electrode. Therefore, this thermal oxide film is not uniform in thickness, and in order to fully prevent the entrance of the hydrogen even at the thinnest portion, the thickness to this extent is required.

FIG. 13 is a cross-sectional view showing a conventional manufacturing method of a floating gate type memory. In this conventional manufacturing method, a stacked gate composed of a tunnel oxide film 52, a floating gate 53, an inter-gate insulating film 54, and a control gate 55 is formed on a semiconductor substrate 51, and thermal oxidation is thereafter applied. As a result, as shown in FIG. 13, large irregularities exit, so that a thermal oxide film 56 nonuniform in thickness is formed.

FIG. 14 is a cross-sectional view showing a conventional manufacturing method of a SONOS type memory. In this conventional manufacturing method, a bit line diffusion layer 62 is formed on a surface of a semiconductor substrate 61, and a storage insulating film 66 composed of a tunnel oxide film 63, a nitride film 64, and a top film 65 is formed thereon. Further, a gate electrode 67 is formed on the storage insulating film 66, and thermal oxidation is thereafter applied. As a result, as shown in FIG. 14, large irregularities exist, so that a thermal oxide film 68 nonuniform in thickness is formed.

However, in semiconductor storage devices formed by the above-described methods, birds' beaks are large to deteriorate coupling. Such deterioration in coupling leads to a problem of deterioration in erase efficiency. This deterioration in erase efficiency is especially noticeable in a memory where erase is conducted near an end portion of a gate electrode and in a memory where erase is conducted in the entire channel. Moreover, if the birds' beak occurs, an insulating film becomes thick at that portion, which leads to deterioration not only in erase efficiency but also in data write efficiency.

There is another problem that it is difficult to stabilize characteristics of the finally manufactured semiconductor storage devices. One of the causes thereof is that at the time of the thermal oxidation, a plurality of wafers are processed at a time, but it is very difficult to keep the temperature in a heating furnace constant at this time. Another cause is that as a result of the thermal oxidation, impurities such as phosphorus which have been introduced into the floating gate and so on tend to segregate in peripheral edge portions thereof.

The present invention was made in view of the above problems, and an object thereof is to provide a semiconductor storage device realizing an improved efficiency in erase/write of data and stabilized characteristics, and to a manufacturing method thereof.

### SUMMARY OF THE INVENTION

As a result of assiduous studies, the inventors of the present application have found out that in a conventional manufacturing method of a semiconductor storage device, the formation of a large birds' beak, segregation of impurities, and the like occur because thermal oxidation is applied for forming an oxide film covering a stacked gate and so on. Then, the inventors of the present invention have found out that adopting plasma processing, instead of the thermal oxidation, as a method of forming a good-quality and precise insulating film can solve the disadvantages described above, and has come up with the following forms of the invention.

A manufacturing method of a first semiconductor storage device according to the present invention is characterized in that after a stacked gate including a tunnel insulating film, a floating gate, an inter-gate insulating film, and a control gate that are stacked on a semiconductor substrate in sequence is formed, a covering insulating film is formed on a surface of the stacked gate by a series of processes including both of or one of a plasma oxidation method and a plasma nitridation method, and an interlayer insulating film in which the stacked gate covered with the covering insulating film is buried is further formed.

The first semiconductor storage device according to the present invention manufactured by such a method includes: a semiconductor substrate; a stacked gate including a tunnel insulating film, a floating gate, an inter-gate insulating film, and a control gate that are stacked on the semiconductor substrate in sequence; a covering insulating film covering the stacked gate; and an interlayer insulating film in which the stacked gate covered with the covering insulating film is buried. This semiconductor storage device is characterized in that the covering insulating film is formed of one kind of insulating film selected from a group consisting of a plasma oxide film, a plasma nitride film, and a plasma oxynitride film.

A manufacturing method of a second semiconductor storage device according to the present invention is characterized in that a storage insulating film including a nitride film having an electric charge capture function is formed on a semiconductor substrate; a gate electrode is formed on the semiconductor substrate via the storage insulating film; thereafter, a covering insulating film is formed on surfaces of the storage insulating film and the gate electrode by a series of processes including both of or one of a plasma oxidation method and a plasma nitridation method; and further an interlayer insulating film in which the storage insulating film and the gate electrode that are covered with the covering insulating film are buried is formed.

The second semiconductor storage device according to the present invention manufactured by such a method includes: a semiconductor substrate; a storage insulating film formed on the semiconductor substrate and including a nitride film having an electric charge capture function; a gate electrode formed on the semiconductor substrate via the storage insulating film; a covering insulating film covering the storage insulating film and the gate electrode; and an interlayer insulating film in which the storage insulating film and the gate electrode that are covered with the covering insulating film are buried. This semiconductor storage device is characterized in that the covering insulating film is formed of one kind of insulating film selected from a group consisting of a plasma oxide film, a plasma nitride film, and a plasma oxynitride film.

### BRIEF DESCRIPTION OF THE DRAWINGS

FIG. 1A and FIG. 1B are cross-sectional views showing a manufacturing method of a semiconductor storage device according to a first embodiment of the present invention;

FIG. 2A and FIG. 2B are views showing the manufacturing method of the semiconductor storage device according to the first embodiment of the present invention, and are cross-sectional views showing a step subsequent to the step shown in FIG. 1A and FIG. 1B;

FIG. 3A and FIG. 3B are views showing the manufacturing method of the semiconductor storage device according to the first embodiment of the present invention, and are cross-sectional views showing a step subsequent to the step shown in FIG. 2A and FIG. 2B;

FIG. 4A and FIG. 4B are views showing the manufacturing method of the semiconductor storage device according to the first embodiment of the present invention, and are cross-sectional views showing a step subsequent to the step shown in FIG. 3A and FIG. 3B;

FIG. 5A and FIG. 5B are views showing the manufacturing method of the semiconductor storage device according to the first embodiment of the present invention, and are cross-sectional views showing a step subsequent to the step shown in FIG. 4A and FIG. 4B;

FIG. 6A and FIG. 6B are views showing the manufacturing method of the semiconductor storage device according to the first embodiment of the present invention, and are cross-sectional views showing a step subsequent to the step shown in FIG. 5A and FIG. 5B;

FIG. 7 is a cross-sectional view showing a state of a plasma insulating film 7 in the first embodiment of the present invention;

FIG. 8A and FIG. 8B are cross-sectional views showing a manufacturing method of a semiconductor storage device according to a second embodiment of the present invention;

FIG. 9A and FIG. 9B are views showing the manufacturing method of the semiconductor storage device according to the second embodiment of the present invention, and are cross-sectional views showing a step subsequent to the step shown in FIG. 8A and FIG. 8B;

FIG. 10A and FIG. 10B are views showing the manufacturing method of the semiconductor storage device according to the second embodiment of the present invention, and are cross-sectional views showing a step subsequent to the step shown in FIG. 9A and FIG. 9B;

FIG. 11 is a cross-sectional view showing a state of a plasma insulating film in the second embodiment of the present invention;

FIG. 12 is a schematic view showing a rough configuration of a plasma processing system including a radial line slot antenna, which is usable in the embodiments of the present invention;

FIG. 13 is a cross-sectional view showing a conventional manufacturing method of a floating gate type memory; and

FIG. 14 is a cross-sectional view showing a conventional manufacturing method of a SONOS type memory.

### DETAILED DESCRIPTION OF THE PREFERRED EMBODIMENTS

Hereinafter, semiconductor storage devices and manufacturing methods thereof according to embodiments of the present invention will be concretely described with reference to the attached drawings. For convenience' sake, the structures of the semiconductor storage devices will be described along with forming methods thereof.

(First Embodiment)

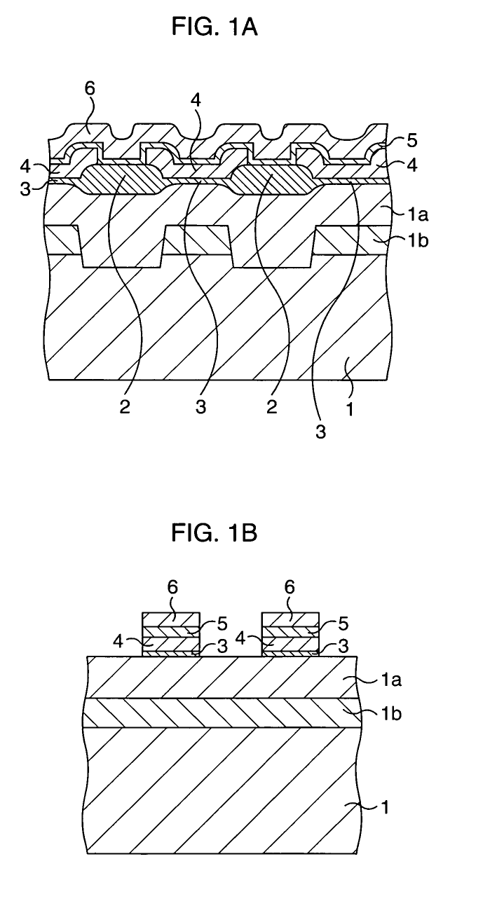

A first embodiment of the present invention will be first described. In the first embodiment, the present invention is applied to a semiconductor storage device with a stacked gate structure. FIG. 1A and FIG. 1B to FIG. 6A and FIG. 6B are cross-sectional views showing, in the order of steps, a manufacturing method of a semiconductor storage device according to the first embodiment of the present invention.

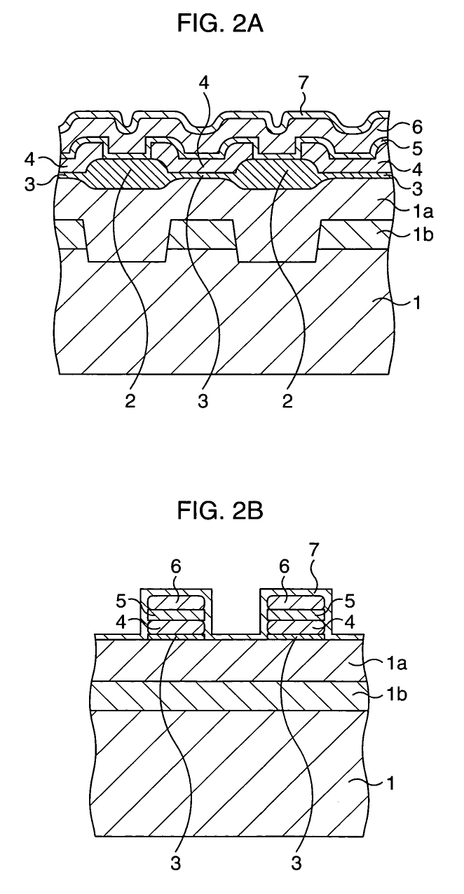

In the semiconductor storage device according to the first embodiment, a plurality of word lines and bit lines are formed in a grid so as to perpendicularly intersect each other. One memory cell is formed near each grid point. FIG. 1B to FIG. 6A correspond to a cross section perpendicular to the bit lines, and FIG. 1B to FIG. 6B correspond to a cross section perpendicular to the word lines. Therefore, FIG. 1A and FIG. 1B show cross sections perpendicular to each other. The same applies to the other FIG. 2A and FIG. 2B to FIG. 6A and FIG. 6B.

In this embodiment, for forming the semiconductor storage device with the above-described layout structure, element isolation insulating films 2 are first formed on a surface of a semiconductor substrate 1 such as a silicon substrate, as shown in FIG. 1A and FIG. 1B, by, for example, a LOCOS method. Next, in order to prevent punch-through under the element isolation insulating films 2, impurities such as boron are ion-implanted into the entire surface to form a diffusion layer 1a. Further, in order to adjust threshold voltage of the memory cells, impurities such as boron are ion-implanted into element regions demarcated by the element isolation insulating films 2 to form a diffusion layer 1b.

In forming these word lines and bit lines, and forming the element isolation insulating films 2 by the LOCOS method, the narrower their minimum line width is, the greater effect of the present invention is exhibited. Specifically, if the minimum line width is 0.5 μm or less, the effect is exhibited, and if 0.25 μm or less, the effect is especially prominent. This is because the width of a birds' beak is not negligible if the line width is narrow. This also applies to a second embodiment.

Next, tunnel insulating films 3 each formed of, for example, a silicon oxide film are formed in the element regions demarcated by the element isolation insulating films 2. Thereafter, for each of the memory cells, a floating gate 4 is formed, and an ONO film (inter-gate insulating film) 5 and a control gate (word line) 6 are further formed. In forming the floating gate 4, after the formation of, for example, a polysilicon film, impurities such as boron are introduced into this polysilicon film by, for example, ion implantation. The ONO film 5 is composed of a silicon nitride film, a silicon oxide film, and a silicon nitride film that are stacked in sequence. A stacked gate is formed of a stack of the tunnel insulating film 3, the floating gate 4, the ONO film 5, and the control gate 6.

At this time, the higher the density of the impurities in the floating gate is, the higher effect of the present invention is exhibited. Specifically, if the density is 1×10¹⁸/cm³ or higher, the effect is exhibited, and if about 1×10¹⁹/cm³, the effect is especially prominent. This is because in a sidewall film formation by low-temperature oxidation/nitridation/oxynitridation which is a characteristic of the present invention, quality deterioration in an insulating film around the floating gate does not occur while in high-temperature heat treatment, it occurs due to the occurrence of segregation of impurities. This segregation is noticeable especially when the impurities are phosphorus.

Further, in the formation of the ONO film 5, the smaller its thickness is, the higher effect of the present invention is exhibited. Specifically, if the total physical film thickness is 40 nm or less, the effect is exhibited, and if 20 nm or less, the effect is especially prominent. This is because if the ONO film is thin, the thickness of the birds' beak is not negligible relative to the thickness of the ONO film itself. More specifically, in the ONO film, if the thickness of the bottom oxide film is 10 nm or less and especially 7 nm or less, the effect is prominent; if the thickness of the nitride film is 20 nm or less and especially 10 nm or less, the effect is prominent; and if the thickness of the top oxide film is 10 nm or less and especially 7 nm, the effect is prominent. This also applies to the second embodiment.

Next, a plasma insulating film (covering insulating film) 7 is formed on upper faces and side faces of the control gates 6 and on side faces of the ONO films 5, the floating gates 4, and the tunnel insulating films 3, that is, on surfaces of the stacked gates. At this time, the plasma insulating film 7 is formed also on a surface of the semiconductor substrate 1. As the plasma insulating film 7, a plasma oxide film, a plasma nitride film, or a plasma oxynitride film can be formed. This plasma insulating film 7 is preferably formed under a temperature range of 650° C. or lower, and may be formed, for example, at about 450° C. Further, the thickness of the plasma insulating film 7 is preferably 9 nm or less, and for example, is about 8 nm.

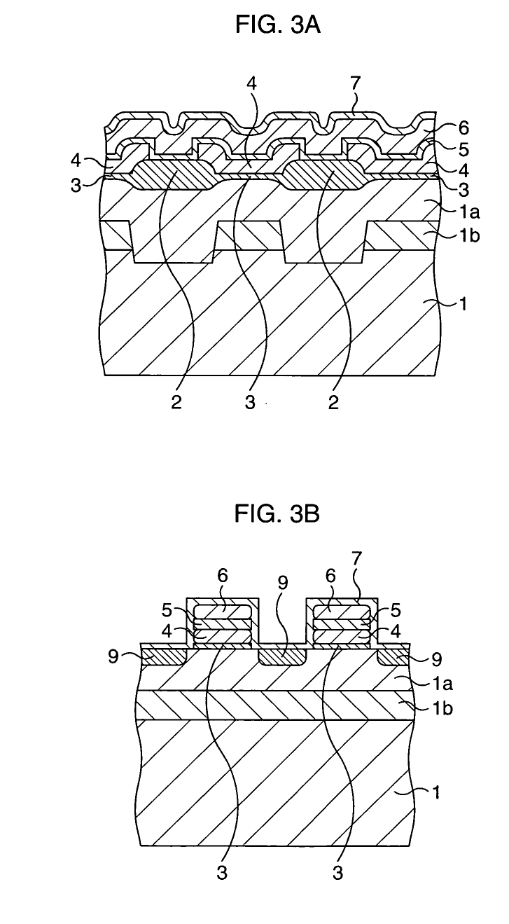

Subsequently, ion implantation is performed with the stacked gates being used as masks, and heat treatment is further applied, so that a low-density diffusion layer 9 is formed in a self-aligned manner as shown in FIG. 3A and FIG. 3B.

At this time, the low-density diffusion layer is diffused under the gates by heat treatment, and the diffusion distance from edges of the gates has to be such that the low-density diffusion layer 9 diffuses at least beyond the birds' beaks. In the present invention, the birds' beak is reduced, so that the spread of the low-density diffusion layer under the gates can be reduced. Since the miniaturization of an element is restricted by a punch-through current from this diffusion layer, the present invention greatly contributes to the miniaturization of an element.

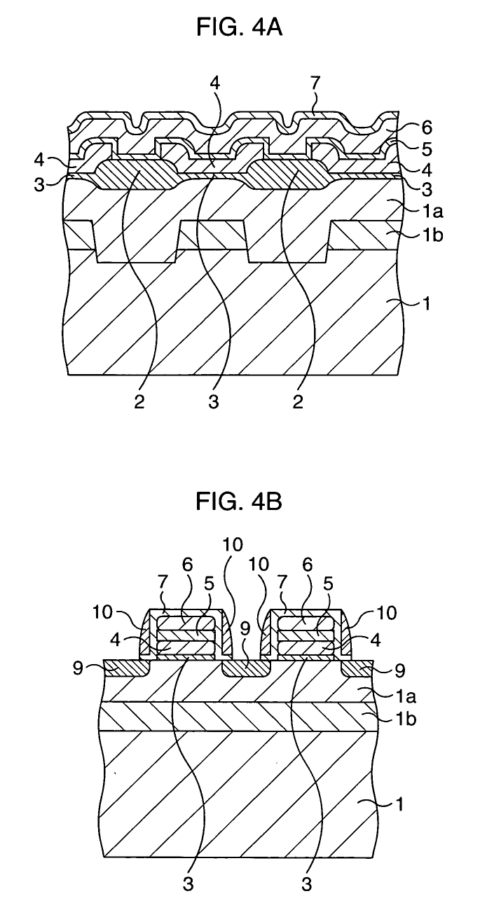

Next, as shown in FIG. 4A and FIG. 4B, sidewall insulating films 10 are formed on side faces of the stacked gates. The sidewall insulating films 10 are formed, for example, in such a manner that a HtO film (high-temperature oxide film) is formed and isotropy etching is thereafter applied. In the plasma insulating film 7 formed on the surface of the semiconductor substrate 1, portions not covered by the sidewall insulating film 10 are finally removed by this isotropy etching, so that the surface of the semiconductor substrate 1 is partly exposed.

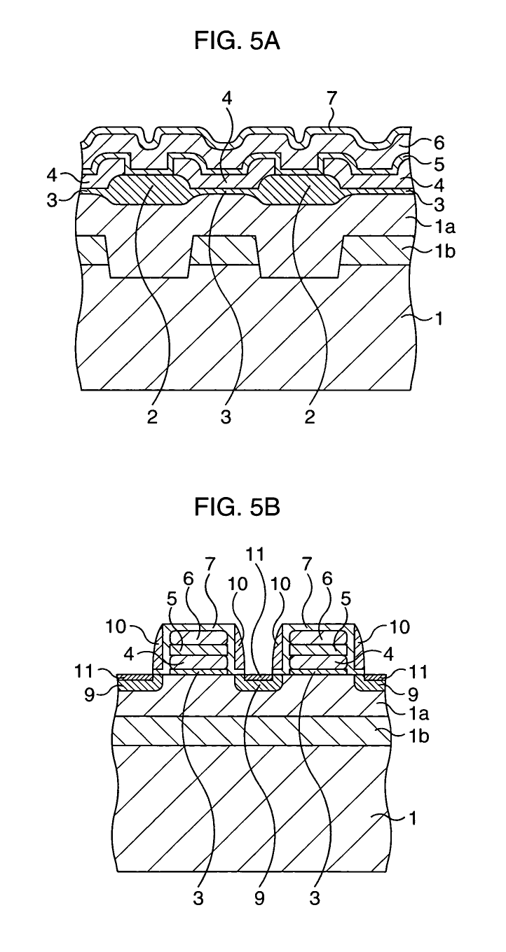

Thereafter, as shown in FIG. 5A and FIG. 5B, ion implantation is performed with a higher density than that in forming the low-density diffusion layer 9, with the stacked gates and the sidewall insulating films 10 being used as masks, and heat treatment is further applied, thereby forming a high-density diffusion layer 11.

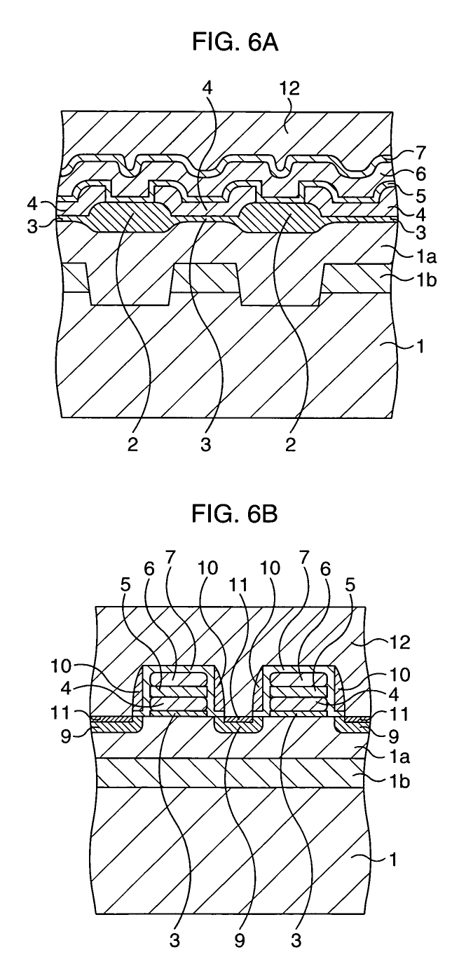

Next, as shown in FIG. 6A and FIG. 6B, an interlayer insulating film 12 is formed on the entire surface. The interlayer insulating film 12 is formed by depositing a silicon oxide film by, for example, a CVD method.

Subsequently, after the formation of contact holes and wirings, and so on, the semiconductor storage device is completed.

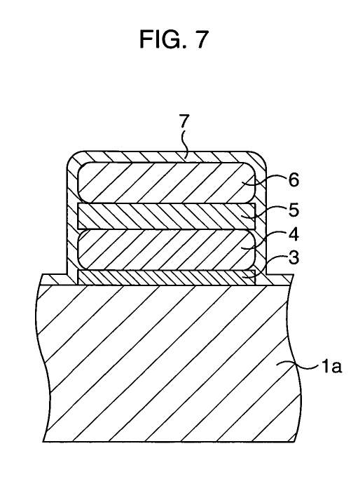

In the first embodiment as described above, as shown in FIG. 2A and FIG. 2B, the plasma insulating film 7 is an insulating film covering the stacked gates. A plasma insulating film is immune to plane orientation of a base film unlike a thermal oxide film. Therefore, as shown in FIG. 7, the thickness of the plasma insulating film 7 becomes substantially uniform over the entire film, and consequently, even if the maximum thickness thereof is not as large as that of a thermal oxide film, hydrogen entrance is prevented when the sidewall insulating film 10 or the interlayer insulating film 12 is formed, and electron leakage is also prevented. The reduction in thickness of this insulating film makes it possible to reduce the birds' beak, so that efficiency in erase/write of data can be improved.

In a floating gate type semiconductor storage device, in write/erase of data, electric charges are exchanged between the floating gate and a semiconductor substrate, and data is read out depending on whether or not the electric charges are captured by the floating gate. Therefore, by reducing the birds' beak as described above, the electric charges can be easily exchanged, so that efficiency in erase and so on is improved.

Further, in forming the plasma insulating film 7, a plurality of wafers are not processed in one heating furnace. Therefore, no influence is given by nonuniform temperature in the furnace. Moreover, the plasma insulating film 7 can be formed under an extremely low temperature compared with a thermal oxide film. Therefore, it is extremely difficult for impurities, for example, phosphorus, in the floating gate 4 to segregate. Consequently, it is possible to obtain a semiconductor storage device whose characteristics are stable among a plurality of wafers.

(Second Embodiment)

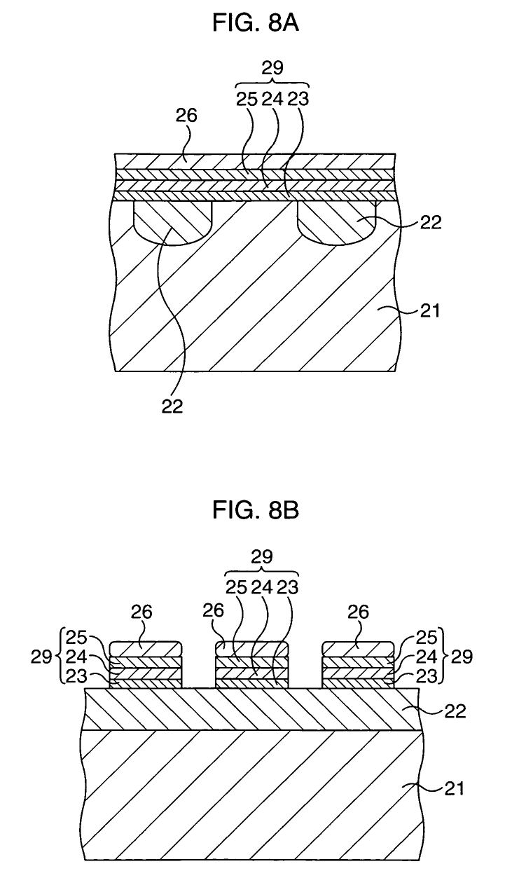

Next, a second embodiment of the present invention will be described. In the second embodiment, the present invention is applied to a semiconductor storage device with a so-called SONOS structure. FIG. 8A and FIG. 8B to FIG. 10A and FIG. 10B are cross-sectional views showing, in the order of steps, a manufacturing method of the semiconductor storage device according to the second embodiment of the present invention. The SONOS structure is a structure of a memory accumulating electric charges in a nitride film, which has sources/drains serving also as buried bit lines and channels parallel to word lines (gate electrodes), and it has a buried bit line structure.

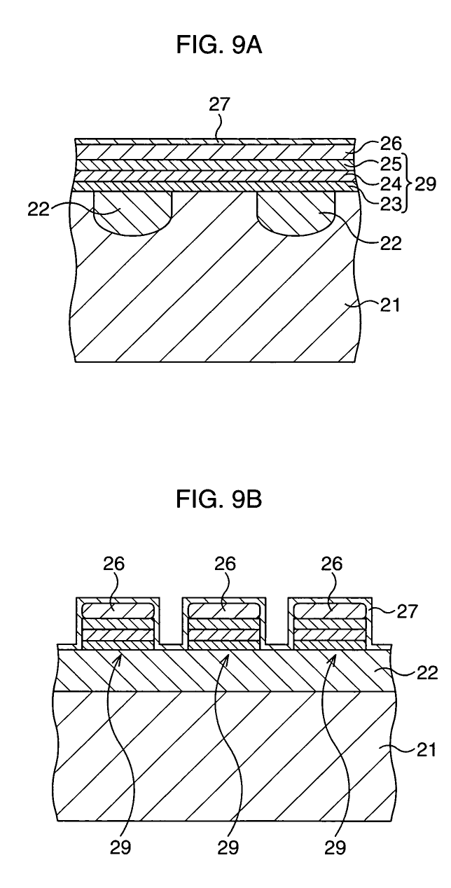

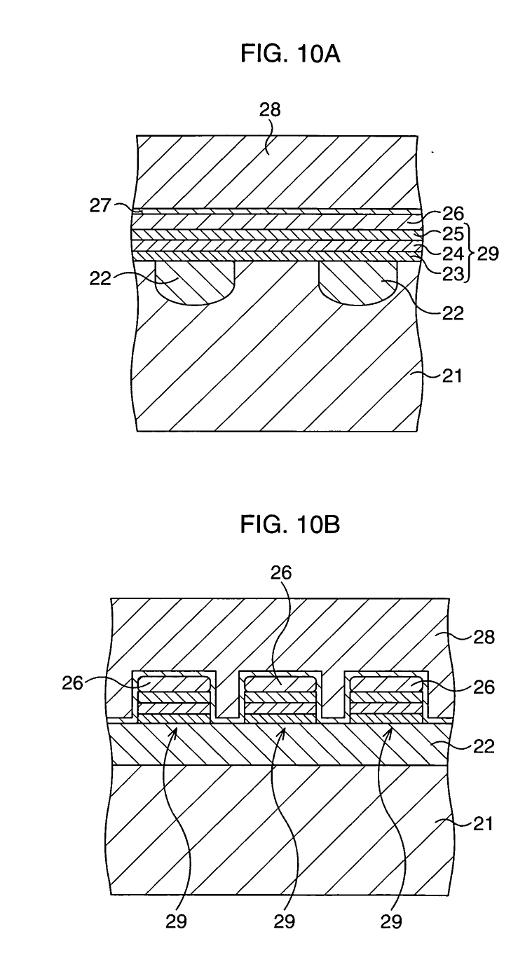

Also in the second embodiment, a plurality of word lines and bit lines are formed in a grid so as to perpendicularly intersect each other. One memory cell is formed near each grid point. Similarly to the first embodiment, FIG. 8A to FIG. 10A correspond to a cross section perpendicular to the bit lines, and FIG. 8B to FIG. 10B correspond to a cross section perpendicular to the word lines. Therefore, FIG. 8A and FIG. 8B show cross sections perpendicular to each other. The same applies to the other FIG. 9A and FIG. 9B, and FIG. 10A and FIG. 10B.

In this embodiment, for manufacturing the semiconductor storage device with the above-described layout structure, ion implantation is first performed into a surface of a semiconductor substrate 21 such as a silicon substrate, with a resist film being used as a mask, thereby forming a bit line diffusion layer (bit lines) 22, as shown in FIG. 8A and FIG. 8B.

Next, a silicon oxide film, a silicon nitride film, a silicon oxide film, and a polysilicon film are stacked in sequence, and patterning is performed, so that multilayer structures each formed of a tunnel insulating film 23, a silicon nitride film 24, a top film 25, and a control gate (word line (gate electrode)) 26 which are stacked in sequence are formed. For forming the control gate 26, for example, the polysilicon film is formed, and thereafter, impurities such as boron are introduced into this polysilicon film by, for example, ion implantation. The tunnel insulating film 23 is formed of the silicon oxide film, and the top film 25 is formed of the silicon oxide film. A storage insulating film 29 is composed of the tunnel insulating film 23, the silicon nitride film 24, and the top film 25. Further, the control gate 26 is formed of the polysilicon film.

Thereafter, as shown in FIG. 9A and FIG. 9B, a plasma insulating film (covering insulating film) 27 is formed on upper faces and side faces of the control gates 26 and on side faces of the tunnel insulating films 23, the storage films 24, and the top films 25. At this time, the plasma insulating film 27 is also formed on a surface of the semiconductor substrate 21. As the plasma insulating film 27, a plasma oxide film, a plasma nitride film, or a plasma oxynitride film can be formed, similarly to the plasma insulating film 7 in the first embodiment. The plasma insulating film 27 is preferably formed under a temperature range of 650° C. or lower, and may be formed at, for example, about 450° C. Further, the thickness of the plasma insulating film 27 is preferably 9 nm or less, and is for example, about 8 nm.

The heat treatment at this time causes impurities in the buried bit lines to diffuse toward the centers of channels, but in the present invention, since the low-temperature treatment is applied, so that the diffusion of the impurities included in the buried bit lines can be reduced. Since the miniaturization of an element is restricted by a punch-through current from this diffusion layer, the present invention greatly contributes to the miniaturization of an element.

Subsequently, as shown in FIG. 10A and FIG. 10B, an interlayer insulating film 28 is formed on the entire surface. The interlayer insulating film 28 is formed by depositing a silicon oxide film by, for example, a CVD method.

Then, after the formation of contact holes and wiring, and so on, the semiconductor storage device is completed.

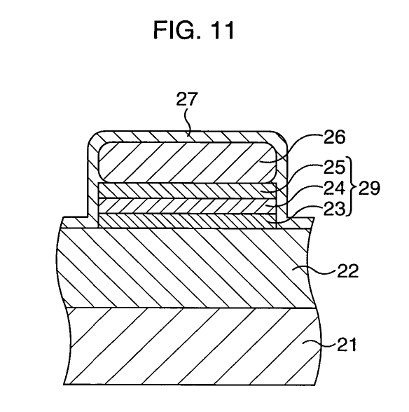

Also in the second embodiment described above, as shown in FIG. 9A and FIG. 9B, the plasma insulating film 27 is an insulating film covering the side faces of the storage film 24. Therefore, as shown in FIG. 11, the thickness of the plasma insulating film 27 is substantially uniform over the entire film, and consequently, even if the maximum thickness thereof is not as large as that of a thermal oxide film, hydrogen entrance is prevented when the interlayer insulating film 28 is formed, and electron leakage is also prevented, similarly to the first embodiment. As a result, it is possible to reduce a birds' beak to enhance efficiency in erase/write of data.

In a SONOS type semiconductor storage device, when data is written/erased, electric charges are exchanged between a storage film formed of a silicon nitride film and a semiconductor substrate, and data is read out depending on whether or not the electric charges are captured on an interface between the storage film and a tunnel insulating film thereunder and in its vicinity. Therefore, by reducing the birds' beak as described above, the electric charges are easily exchanged, so that efficiency in erase and so on is improved.

Further, similarly to the first embodiment, it is possible to avoid unstable characteristics that may cause nonuniformity in film deposition temperature and segregation of phosphorus.

In the second embodiment, the sidewall insulating films are not formed on side faces of the control gates 26, but the sidewall insulating films may be formed. Such sidewall insulating films may be formed concurrently with the formation of sidewall insulating films of transistors constituting, for example, peripheral circuits.

Note that for forming the plasma oxide film, radical O*, radical N*, or radical NH* is generated in an atmosphere of plasma of gas containing, for example, O₂, N₂, or NH₃. At this time, source gas used for growing the plasma insulating film may contain rare gas such as, for example, Kr or Ar, or may contain H₂.

Further, a forming method of the plasma oxynitride film and the plasma nitride film and a plasma processing system used for the formation thereof are not limited to specific ones, but a system as described below may be used to form the plasma oxide film or the plasma nitride film.

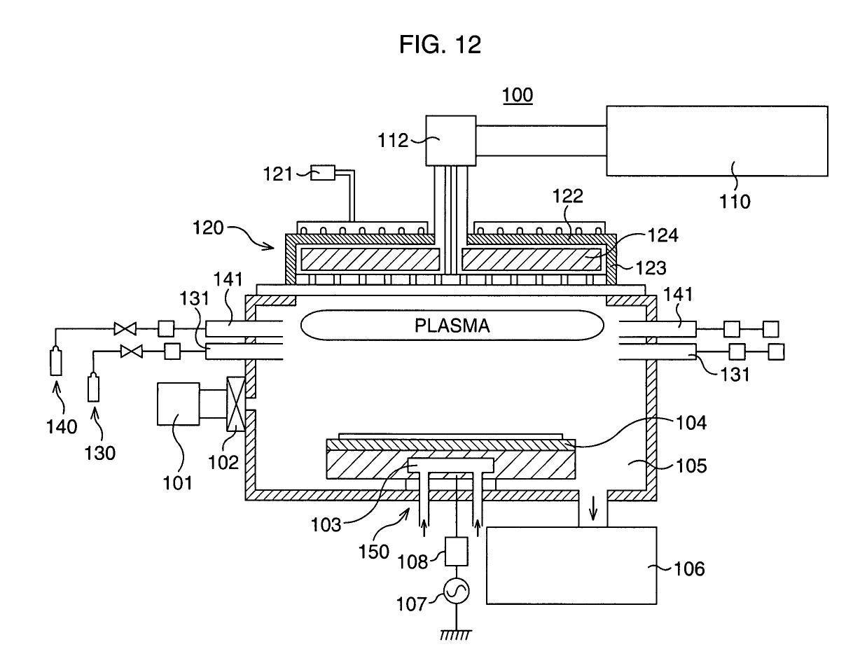

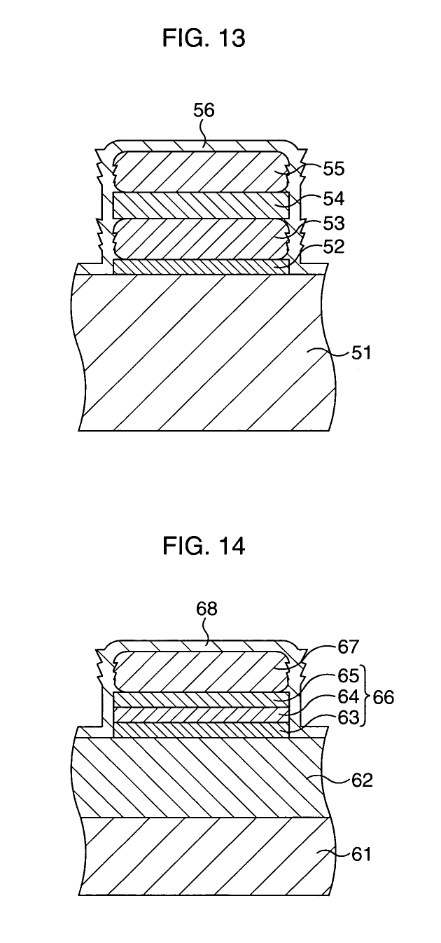

Specifically, a plasma processing system including a radial line slot antenna as shown in FIG. 12 is used to form the plasma oxynitride film or the plasma nitride film. This plasma processing system 100 includes: a gate valve 102 communicating with a cluster tool 101; a process chamber 105 capable of housing a susceptor 104 that places thereon an object to be proceed W (the semiconductor substrate 1 in this embodiment) and that includes a cooling jacket 103 cooling the object to be processed W in plasma processing; a high-vacuum pump 106 connected to the process chamber 105; a microwave source 110; an antenna member 120; a bias high-frequency power source 107 and a matching box 108 that form, together with this antenna member 120, a system called ion plating; gas supply systems 130, 140 having gas supply rings 131, 141; and a temperature control part 150 controlling the temperature of the object to be processes W.

The microwave source 110 is constituted of, for example, a magnetron and is capable of generating a microwave (for example, 5 kW) of normally 2.45 GHz. A transmission mode of the microwave is thereafter converted to a TM mode, a TE mode, a TEM mode, or the like by a mode converter 112.

The antenna member 120 has a temperature adjusting plate 122 and a housing member 123 (a dielectric plate 230). The temperature adjusting plate 122 is connected to a temperature control device 121, and the housing member 123 houses a slow wave member 124 and a slot electrode (not shown) in contact with the slow wave member 124. This slot electrode is called a radial line slot antenna (RLSA) or a super-high-performance planar antenna. However, in this embodiment, other type of antenna, for example, a single layer waveguide planar antenna, a dielectric substrate/parallel plate slot array, or the like may be applied.

When a plasma processing system including such a radial line slot antenna is used for film deposition, ion irradiation energy of plasma is preferably set to 7 eV or less, and potential energy of plasma is preferably set to 10 eV or less.

With the use of the above-described plasma processing system, the plasma insulating film can be formed by a series of processes including a plasma oxidation method and a plasma nitridation method or including at least one of them.

Further, in the above-described embodiments, the present invention is applied to the floating gate type or the SONOS type, but embodiments to which the present invention is applicable are not limited to them, and for example, the present invention is also applicable to a MNOS type semiconductor storage device. When the present invention is applied to the MNOS type semiconductor storage device, a silicon oxide film and a silicon nitride film are stacked in sequence on a semiconductor substrate to form a storage insulating film, and thereafter, gate electrodes are formed thereon. Subsequently, a plasma insulating film is formed on surfaces of the storage insulating film and the gate electrodes.

Industrial Applicability

According to the present invention, since a covering insulating film covering a floating gate or a gate electrode is formed by plasma processing, high-temperature heat treatment is not required, a birds' beak is reduced, and efficiency in write/erase is high, so that stable characteristics can be obtained.

1. A semiconductor storage device comprising:
a semiconductor substrate;
a stacked gate including a tunnel insulating film, a floating gate, an inter-gate insulating film, and a control gate that are stacked on said semiconductor substrate in sequence;
a covering insulating film covering said stacked gate; and
an interlayer insulating film in which said stacked gate covered with said covering insulating film is buried,
wherein said covering insulating film is formed of one kind of insulating film selected from a group consisting of a plasma oxide film, a plasma nitride film, and a plasma oxynitride film.

2. The semiconductor storage device according to claim 1, wherein phosphorus is introduced into said floating gate.

3. The semiconductor storage device according to claim 1, wherein said covering insulating film is 9 nm or less in thickness.

4. The semiconductor storage device according to claim 1, wherein a density of impurities in the floating gate is 1×10¹⁸/cm³ or higher.

5. The semiconductor storage device according to claim 1, wherein said inter-gate insulating film is 40 nm or less in thickness.

6. The semiconductor storage device according to clam 1, further comprising a sidewall insulating film formed on a side face of said covering insulating film.

7. A semiconductor storage device, comprising:
a semiconductor substrate;
a storage insulating film formed on said semiconductor substrate and including a nitride film having an electric charge capture function;
a gate electrode formed on said semiconductor substrate via said storage insulating film;
a covering insulating film covering said storage insulating film and said gate electrode; and
an interlayer insulating film in which said storage insulating film and said gate electrode that are covered with said covering insulating film are buried,
wherein said covering insulating film is formed of one kind of insulating film selected from a group consisting of a plasma oxide film, a plasma nitride film, and a plasma oxynitride film.

8. The semiconductor storage device according to claim 7, wherein phosphorus is introduced into said gate electrode.

9. The semiconductor storage device according to claim 7,
wherein said storage insulating film includes:
said nitride film; and
a first oxide film formed between the nitride film and said semiconductor substrate.

10. The semiconductor storage device according to claim 9, wherein said storage insulating film further includes a second oxide film formed between the nitride film and said gate electrode.

11. The semiconductor storage device according to claim 7, further comprising a sidewall insulating film formed on a side face of said covering insulating film.

12. A manufacturing method of a semiconductor storage device, comprising the steps of:
forming a stacked gate including a tunnel insulating film, a floating gate, an inter-gate insulating film, and a control gate that are stacked on a semiconductor substrate in sequence;
forming a covering insulating film on a surface of the stacked gate by a series of processes including both of or one of a plasma oxidation method and a plasma nitridation method; and
forming an interlayer insulating film in which the stacked gate covered with the covering insulating film is buried.

13. The manufacturing method of the semiconductor storage device according to claim 12, further comprising the step of introducing phosphorus into the floating gate prior to said step of forming the covering insulating film.

14. The manufacturing method of the semiconductor storage device according to claim 12, wherein the covering insulating film is 9 nm or less in thickness.

15. The manufacturing method of the semiconductor storage device according to claim 12, wherein a density of impurities in the floating gate is 1×10¹⁸/cm³ or higher.

16. The manufacturing method of the semiconductor storage device according to claim 12, wherein the inter-gate insulating film is 40 nm or less in thickness.

17. The manufacturing method of the semiconductor storage device according to claim 12, further comprising the step of forming a sidewall insulating film on a side face of the covering insulating film.

18. The manufacturing method of the semiconductor storage device according to claim 12, wherein said step of forming the covering insulating film is conducted in an atmosphere of plasma of source gas containing at least one kind of molecule selected from a group consisting of O₂, N₂, and NH₃.

19. The manufacturing method of the semiconductor storage device according to claim 12, wherein said step of forming the covering insulating film is conducted under a temperature range of 650° C. or lower.

20. A manufacturing method of a semiconductor storage device, comprising the steps of:
forming a storage insulating film including a nitride film having an electric charge capture function on a semiconductor substrate;
forming a gate electrode on the semiconductor substrate via the storage insulating film;
forming a covering insulating film on surfaces of the storage insulating film and the gate electrode by a series of processes including both of or one of a plasma oxidation method and a plasma nitridation method; and
forming an interlayer insulating film in which the storage insulating film and the gate electrode that are covered with the covering insulating film are buried.

21. The manufacturing method of the semiconductor storage device according to claim 20, further comprising the step of introducing phosphorus into the gate electrode prior to said step of forming the covering insulating film.

22. The manufacturing method of the semiconductor storage device according to claim 20,
wherein said step of forming the storage insulating film comprises the steps of:
forming a first oxide film on the semiconductor substrate; and
forming the nitride film on the first oxide film.

23. The manufacturing method of the semiconductor storage device according to claim 22, wherein said step of forming the storage insulating film further comprises the step of forming a second oxide film on the nitride film.

24. The manufacturing method of the semiconductor storage device according to claim 20, further comprising the step of forming a sidewall insulating film on a side face of the covering insulating film.

25. The manufacturing method of the semiconductor storage device according to claim 20, wherein said step of forming the covering insulating film is conducted in an atmosphere of plasma of source gas containing at least one kind of molecule selected from a group consisting of O₂, N₂, and NH₃.

26. The manufacturing method of the semiconductor storage device according to claim 25, wherein said step of forming the covering insulating film comprises the step of generating, in said atmosphere, at least one kind of radical selected from a group consisting of at least radical O*, radical N*, and radical NH*.

27. The manufacturing method of the semiconductor storage device according to claim 25, wherein the source gas further contains rare gas.

28. The manufacturing method of the semiconductor storage device according to claim 27, wherein the rare gas contains at least one kind of molecule selected from a group consisting of Kr and Ar.

29. The manufacturing method of the semiconductor storage device according to claim 25, wherein the source gas further contains H₂.

30. The manufacturing method of the semiconductor storage device according to claim 25, wherein in said step of forming the covering insulating film, ion radiation energy of the plasma is set to 7 eV or less.

31. The manufacturing method of the semiconductor storage device according to claim 25, wherein in said step of forming the covering insulating film, potential energy of the plasma is set to 10 eV or less.

32. The manufacturing method of the semiconductor storage device according to claim 25, wherein in said step of forming the covering insulating film, a microwave emitted from a planar antenna in which a plurality of slits are formed is used to excite the source gas, thereby generating the plasma.

33. The manufacturing method of the semiconductor storage device according to claim 32, wherein a radial line slot antenna is used as the planar antenna.

34. The manufacturing method of the semiconductor storage device according to claim 20, wherein said step of forming the covering insulating film is conducted under a temperature range of 650° C. or lower.
